(19) United States
(12) Patent Application Publication
(10) Pub. No.: US 2022/0375777 A1
(43) Pub. Date: Nov. 24, 2022

(54) STRUCTURE OF MOUNTING TABLE AND SEMICONDUCTOR PROCESSING APPARATUS

(71) Applicant: Tokyo Electron Limited, Tokyo (JP)

(72) Inventors: Naoyuki SATOH, Miyagi (JP); Yasuharu SASAKI, Miyagi (JP)

(73) Assignee: Tokyo Electron Limited, Tokyo (JP)

(21) Appl. No.: 17/878,912

(22) Filed: Aug. 2, 2022

Related U.S. Application Data
(63) Continuation of application No. 16/794,691, filed on Feb. 19, 2020, now abandoned.
Application No. 16/794,691 is a continuation of application No. 15/398,893, filed on Jan. 5, 2017, now abandoned.

(30) Foreign Application Priority Data
Jan. 15, 2016 (JP) 2016-006631

(51) Int. Cl. H01L 21/683; H01J 37/32; H01L 21/67

(52) U.S. Cl. CPC H01L 21/6833; H01L 21/6831; H01J 37/32715; H01J 37/32009; H01J 37/32642; H01L 21/67069; H01L 21/67109; H01J 2237/334

(57) ABSTRACT

A mounting table includes a substrate mounting area for placing a substrate; a focus ring mounting area for placing a focus ring, so that the focus ring surrounds the substrate mounting area; an electrode that electrostatically attracts the focus ring; ring-shaped first and second elastic bodies, wherein the second elastic body is placed at an inner side in a radial direction compared to the first, elastic body, and the first elastic body and the second elastic body directly contact a back surface of the focus ring, the focus ring mounting area includes a recess that is provided with a supply hole that supplies a heat transfer gas to the recess, the electrode extends inward and outward in a radial direction with respect to a location of the supply hole, and the first elastic body and the second elastic body are placed in the recess.

### CROSS-REFERENCE TO RELATED APPLICATIONS

The present application is a continuation application of U.S. application Ser. No. 16/794,691, filed on Feb. 19, 2020, which is a continuation application filed under 35 U.S.C. 111(a) claiming the benefit under 35 U.S.C. 120 of U.S. patent application Ser. No. 15/398,893 filed on Jan. 5, 2017 (now Abandoned), which is based on and claims priority to Japanese Application No. 2016-006631, filed on Jan. 15, 2016, the entire contents of each are hereby incorporated herein by reference.

### BACKGROUND OF THE INVENTION

### 1. Field of the Invention

The present disclosure relates to a structure of a mounting table and a semiconductor processing apparatus.

### 2. Description of the Related Art

In a semiconductor manufacturing device, a substrate can be held on a mounting table by electrostatic attraction force generated by an electrostatic chuck mounted on the mounting table. It has been proposed to control temperature of a focus ring by enhancing heat transfer between the focus ring and the mounting table whose temperature is controlled by coolant. The heat transfer between the focus ring and the mounting table can be enhanced by causing the focus ring to be electrostatically attracted to the mounting table by the electrostatic chuck, and by supplying a heat transfer gas to a back surface of the focus ring (cf. Patent Document 1 (Japanese Unexamined Patent Publication No. 2015-62237), for example).

Furthermore, it has been proposed to promote heat transfer between the focus ring and the mounting table by interposing a heat transfer material between the focus ring and the mounting table (cf. Patent Document 2 (Japanese Unexamined Patent Publication No. 2002-16126)). Furthermore, it has been proposed to cause the focus ring and the mounting table to be attracted each other by a magnet; to arrange O-rings at an inner peripheral portion and an outer peripheral portion, respectively, of the focus ring and the mounting table; and to supply a heat transfer gas inside the focus ring and the mounting table (cf. Patent Document 3 (Japanese Unexamined Patent Publication No. 2015-41451)).

### SUMMARY OF THE INVENTION

According to an aspect of the present invention, there is provided a mounting table including a substrate mounting area on which a substrate is placed; a focus ring mounting area on which a focus ring is placed, so that the focus ring surrounds the substrate mounting area; an electrode that electrostatically attracts the placed focus ring; a ring-shaped first elastic body that is placed at a first, ring-shaped part of the focus ring mounting area; a ring-shaped second elastic body that is placed at a second ring-shaped part, wherein the second ring-shaped part is placed at an inner side in a radial direction compared to the first ring-shaped part, wherein the first elastic body and the second elastic body directly contact a back surface of the placed focus ring, wherein the focus ring mounting area includes a recess, and the recess is provided with a supply hole that supplies a heat transfer gas to the recess, wherein the electrode extends inward and outward in the radial direction with respect to a location of the supply hole, and wherein the first elastic body and the second elastic body are placed in the recess of the focus ring mounting area.

Other objects, features and advantages of the present invention will become more apparent from the following detailed description when read in conjunction with the accompanying drawings.

### BRIEF DESCRIPTION OF THE DRAWINGS

FIG. 1 is a vertical cross-sectional view illustrating an example of a semiconductor manufacturing apparatus according to an embodiment;

FIGS. 2A and 2B are diagrams illustrating an example of a structure of a mounting table according to the embodiment; and

FIG. 3 is a diagram illustrating an example of a relationship between a thickness of an elastic body and relative permittivity according to the embodiment.

### DESCRIPTION OF THE PREFERRED EMBODIMENTS

Embodiments of the present invention are described below by referring to the accompanying drawings. Note that, in the specification and the drawings, similar reference numerals may be attached to substantially the same configurations, and thereby duplicate explanations may be omitted.

In the technique of Patent Document 1, the attraction force of the focus ring may not be stabilized due to variations in temperature and a slight variation in size of the attraction surface. It is possible that the focus ring that is initially attracted by the mounting table peels off from the mounting table, as time elapses. In this case, the heat transfer gas supplied to the back surface of the focus ring may leak, and it may become difficult to favorably control the temperature of the focus ring.

In the technique of Patent Document 2, the temperature of the focus ring is fixed according to the specification of the heat transfer material, so that it may be difficult to properly control the temperature of the focus ring. In the technique of Patent Document 3, a dedicated magnet is used for enhancing adhesion between the focus ring and the mounting table. Here, it is not considered to control the temperature of the focus ring by utilizing the electrostatic attraction force of the electrostatic chuck for holding the substrate.

There is a need for a technique for properly controlling the temperature of the focus ring while electrostatically attracting the focus ring to the electrostatic chuck.

According to the technique described below, the temperature of the focus ring can be properly controlled while electrostatically attracting the focus ring to the electrostatic chuck.

### [Semiconductor Manufacturing Apparatus]

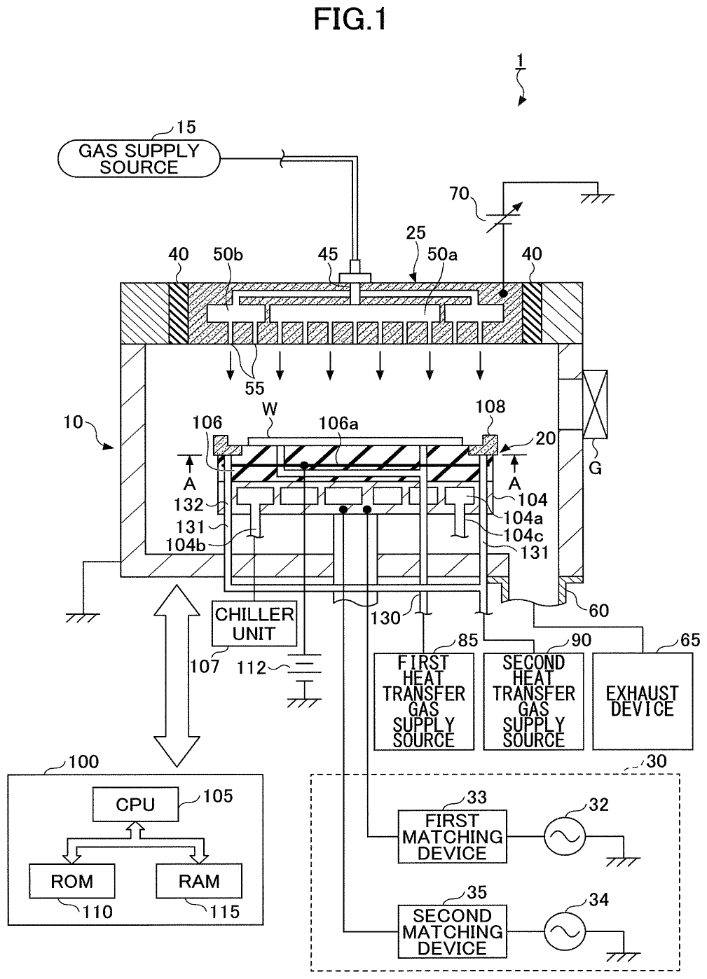

First, an example of a semiconductor manufacturing apparatus 1 according to the embodiment is described by referring to FIG. 1. The semiconductor manufacturing apparatus 1 according to the embodiment is a capacitively coupled type parallel flat plate semiconductor manufacturing apparatus; and includes an approximately cylindrical processing container 10. Alumite treatment (anodization treatment) is applied to an inner surface of the processing container.

A mounting table 20 is installed at a bottom part of the processing container 10; and the mounting table 20 is for placing a semiconductor wafer (which is referred to as the “wafer,” hereinafter) W thereon. The wafer W is an example of an object to be processed. The mounting table 20 is formed of, for example, aluminum (Al), titanium (Ti), silicon carbide (SiC), and so forth. On an upper surface of the mounting table 20, an electrostatic chuck 106 is provided, which is for electrostatically attracting the wafer W. The electrostatic chuck 106 is formed of insulators, such as alumina; and the electrostatic chuck 106 has a structure such that a chuck electrode 106a is nipped between the insulators. A direct current voltage source 112 is coupled to the electrostatic chuck 106. By applying a direct current voltage to the chuck electrode 106a from the direct current voltage source 112, the wafer W is electrostatically attracted to the electrostatic chuck 106 by Coulomb force.

The mounting table 20 is supported by a support 104. Inside the support 104, a coolant flow channel 104a is formed. A coolant inlet pipe 104b is connected to the coolant flow channel 104a; and a coolant outlet pipe 104c is connected to the coolant, flow channel 104a. A cooling medium (which is referred to as the “coolant,” hereinafter), such as cooling water or brine, that is output from a chiller unit 107 flows to the coolant inlet pipe 104b; the coolant flow channel 104a; the coolant outlet pipe 104c; and the chiller unit 107, to circulate. The heat of the mounting table 20 and the electrostatic chuck 106 is removed by the circulating coolant; and the mounting table 20 and the electrostatic chuck 106 are cooled.

A focus ring 108 is disposed at an outer edge portion of the electrostatic chuck 106; and the focus ring 108 enhances intra-plane uniformity of plasma generated in the processing container 10 with respect to the wafer W. The focus ring 108 may be formed of silicon. When a direct current voltage is applied to the chuck electrode 106a, the focus ring 108 is attracted by the electrostatic chuck 106 by the Coulomb force.

The first heat transfer gas supply source 85 supplies a heat transfer gas, such as He gas (helium gas) or Ar gas (argon gas), to a back surface of the wafer W on the electrostatic chuck 106 through a first gas supply line 130. In the above-described configuration, the temperature of the wafer W is controlled by the coolant that circulates through the coolant flow channel 104a, and by the heat transfer gas supplied to the back surface of the wafer.

A second heat transfer gas supply source 90 supplies a heat transfer gas, such as He gas or Ar gas, to a back surface of the focus ring 108 on the electrostatic chuck 106 through a second gas supply line 131 and a gas flow channel 132. In the above-described configuration, the temperature of the focus ring 108 is controlled by the coolant that circulates the coolant flow channel 104a, and by the heat transfer gas supplied to the back surface of the focus ring 108.

The mounting table 20 is coupled to a power supply device 30 for supplying dual frequency superposed power. A power supply device 30 includes a first high frequency power source 32 for supplying high frequency power HF for generating plasma with a first frequency; and a second high frequency power source 34 for supplying high frequency power LF for generating a bias voltage. The first high frequency power source 32 is electrically coupled to the mounting table 20 through a first matching device 33. The second high frequency power source 34 is electrically coupled to the mounting table 20 through a second matching device 35. The first high frequency power source 32 applies, for example, high frequency power He with a frequency of 60 MHz to the mounting table 20. The second high frequency power source 34 applies, for example, high frequency power LF with a frequency of 13.56 MHz to the mounting table 20. Here, the first high frequency power source 32 according to the embodiment applies the first high frequency power to the mounting table 20. However, the embodiment is not limited to this; and the first high frequency power source 32 may apply the first high frequency power to a gas shower head 25. In the above description, the example is described in which the dual frequency superposed power is supplied. However, the embodiment is not limited to the dual frequency superposed power. For example, three frequency superposed power or a single frequency power may be supplied.

The first matching device 33 functions, so that internal (or output) impedance of the first high frequency power source 32 apparently matches the load impedance when plasma is generated in the processing container 10. The second matching device 35 functions, so that internal (or output) impedance of the second high frequency power supply 34 apparently matches the load impedance when plasma is generated in the processing container 10.

The gas shower head 25 is attached to a ceiling part of the processing container 10. The gas shower head 25 closes the opening of the ceiling part of the processing container 10 through a shield ring 40 covering a peripheral edge part of the gas shower head 25. A variable DC power supply 70 is coupled to the gas shower head 25. A negative DC (a DC voltage) is output from the variable DC power supply 70. The gas shower head 25 is formed of silicon.

In the gas shower head 25, a gas inlet port 45 is formed, which is for drawing gas. Inside the gas shower head 25, a diffusion chamber 50a is formed at the central part; and a diffusion chamber 50b is formed at the edge part. The diffusion chamber 50a is branched from the gas inlet port 45; and the diffusion chamber 50b is branched from the gas inlet port 45. The gas output from the gas supply source 15 is supplied to the diffusion chambers boa and 50b through the gas inlet port 45; and the gas is diffused in the diffusion chambers 50a and 50b to be drawn toward the wafer W through multiple gas supply holes 55.

An exhaust port 60 is formed on the bottom surface of the processing container 10. The gas inside the processing container 10 is exhausted by the exhaust device 65 connected to the exhaust port 60. In this manner, a predetermined vacuum state is maintained in the inner part of the processing container 10. A gate valve G is formed on a side wall of the processing container 10. The gate valve G is opened and closed for loading and unloading the wafer W from the processing container 10.

The semiconductor manufacturing apparatus 1 is provided with a controller 100 for controlling the operation of the entire apparatus. The controller 100 includes a central processing unit (CPU) 100; a read-only memory (ROM) 110; a random access memory (RAM) 115, and so forth. The CPU 105 executes a desired process, such as etching, in accordance with various types of recipes (protocols) stored in these storage areas. In each recipe, control information for controlling the device in accordance with a plasma processing condition, such as an etching condition, is described. The control information includes, for example, a process time, pressure (for exhausting the gas), high frequency power and voltage, flow rates of various types of gas, the temperature inside the processing container (e.g., the temperature of the upper electrode, the temperature of the side wall of the processing container, the temperature of the wafer W, and the temperature of the electrostatic chuck), and the temperature of the coolant output from the chiller unit 107. The recipes indicating these programs and processing conditions may be stored in a hard disk or a semiconductor memory. Furthermore, the recipe may be stored in a storage medium that can be read by a portable computer, such as a CD-ROM or a DVD. Then, the storage medium may foe set in a predetermined position, so that the recipe can be read out from the storage medium.

In the semiconductor manufacturing apparatus 1 with such a configuration, for executing a plasma processing (e.g., etching) to the wafer W, the gate valve G is opened; the wafer W is loaded into the processing container 10; and the wafer W is placed on the mounting table 20 and the gate valve G is closed. Upon a DC voltage being applied from the direct current voltage source 112 to the chuck electrode 106a, the wafer W and the focus ring 108 are electrostatically attracted by the electrostatic chuck 100, and thereby the the wafer W and the focus ring 108 are held on the mounting table 20.

Subsequently, a processing gas, the fist high frequency power, and the second high frequency power are supplied inside the processing container 10 to generate plasma. By the generated plasma, a plasma process, such as plasma etching, is applied to the wafer W. After completing the plasma process, a DC voltage opposite in polarity with respect to the DC voltage for attracting the wafer W is applied to the chuck electrode 106a from the direct current voltage source 112. In this manner, the charge on the wafer W is removed, and the wafer W is caused to be separated from the electrostatic chuck 106. Opening/closing of the gate valve G is controlled, and the wafer W is unloaded from the processing container 10.

### [Structure of the Mounting Table]

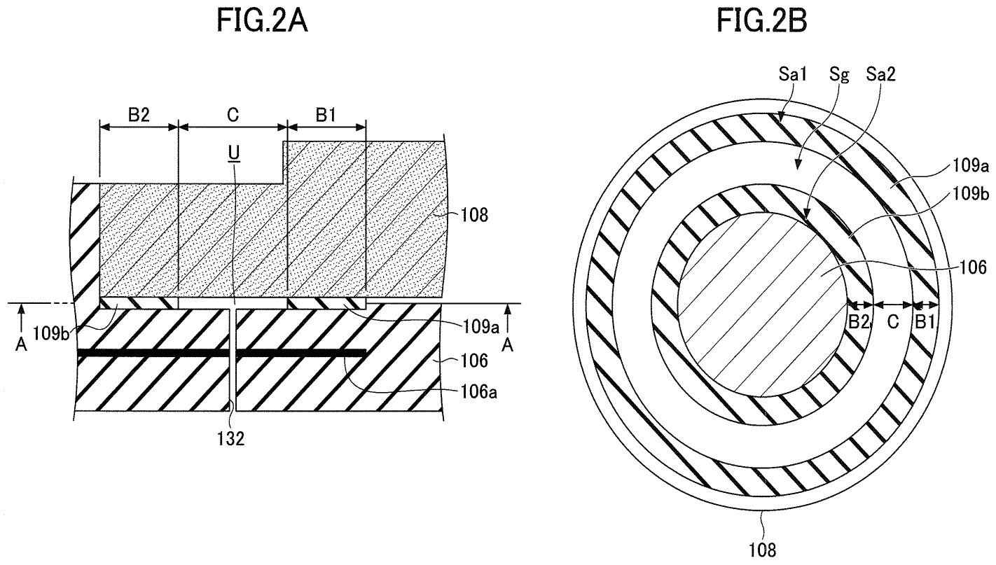

Next, an example of a structure of the mounting table 20 according to the embodiment is described by referring to FIG. 1 and FIGS. 2A and 2B. FIG. 2A is a diagram magnifying and illustrating the focus ring 108 and the structure in the vicinity of the focus ring 108, in the structure of the mounting table 20 according to the embodiment. FIG. 2B is a cross-sectional view along A-A in FIG. 1 and FIG. 2A.

As illustrated in FIG. 2A, a first elastic body 109a and a second elastic body 109b are formed on the boundary surface between the electrostatic chuck 106 and the focus ring 108 according to the embodiment. As illustrated in FIG. 2A and FIG. 2B, the first elastic body 109a is arranged in a ring shape at an outer peripheral portion of the boundary surface between the focus ring 108 and the electrostatic chuck 106. The second elastic body 109b is arranged in a ring shape at an inner peripheral portion of the boundary surface between the focus ring 108 and the electrostatic chuck 106. The width B1 of the first elastic body 109a in the radial direction may be equal to or may not be equal to the width B2 of the second elastic body 109b in the radial direction. The first elastic body 109a and the second elastic body 109b are separated from each other by a distance C. As a result, as illustrated in FIG. 2A, a space U that is sealed by the first elastic body 109a and the second elastic body 109b is formed on the boundary surface between the focus ring 108 and the electrostatic chuck 106. A heat transfer gas, such as He gas, is supplied to the space U from the gas flow channel 132.

The focus ring 108 and the electrostatic chuck 106 are formed of a hard inorganic material. The first elastic body 109a and the second elastic body 109b are formed of, for example, a resin that is softer than the inorganic material. Thus, the first elastic body 109a and the second elastic body 109b function as cushion materials and sealing materials on the boundary surface between the focus ring 103 and the electrostatic chuck 106. In this manner, leakage of the heat transfer gas from the space U can be suppressed. As a result, the heat transfer effect between the focus ring 108 and the electrostatic chuck 106 can be enhanced, and the temperature controllability of the focus ring 108 can be enhanced.

The temperature of the electrostatic chuck 106 is controlled to be a predetermined temperature by the temperature of the coolant. The electrostatic chuck 106 is formed of aluminum, so that the thermal expansion of the electrostatic chuck 106 is greater than the thermal expansion of the focus ring 108. In particular, in the plasma process in which the temperature of the electrostatic chuck 106 is adjusted to be different temperatures, which are in a low temperature range (e.g., 20° C.) and in a high temperature range (e.g., 50° C.), respectively, and the process is alternately performed at the low temperature and the high temperature, so that the shape of the electrostatic chuck 106 is deformed in the vicinity of the focus ring 108. As a result, on the boundary surface between the focus ring 108 and the electrostatic chuck 106, the sealing property is decreased, and the leakage amount of the heat transfer gas is increased. Furthermore, the thickness of the wafer W is approximately 0.8 mm, so that the wafer W is easily bent. The thickness of the focus ring 108 is greater than or equal to 3 mm, so that bending of the focus ring 106 is difficult. Consequently, the state of the boundary surface between the focus ring 108 and the electrostatic chuck 106 is such that leakage of the heat transfer gas tends to occur due to the deformation of the shape of the electrostatic chuck 106 and the difficulty to deform the focus ring 108.

However, according to the structure of the mounting table 20 according to the embodiment, on the boundary surface between the focus ring 108 and the electrostatic chuck 106, the first elastic body 109a and the second elastic body 109b function as the cushion materials and the sealing materials. Thus, the heat transfer gas can be prevented from leaking from the space U. Consequently, the heat, transfer effect between the focus ring 108 and the electrostatic chuck 106 can be enhanced.

Additionally, dielectrics having relative permittivity in a predetermined range are used as the resins forming the first elastic body 109a and the second elastic body 109b, respectively. The predetermined range is described below. Consequently, the first elastic body 109a and the second elastic body 109b themselves electrostatically attract the electrostatic chuck 106. By further enhancing the electrostatic attraction force between the focus ring 108 and the electrostatic chuck 106 in this manner, the focus ring 108 can be stably held on the mounting table 20.

For example, as the materials of the first elastic body 109a and the second elastic body 109b, a perfluoroelastomer material can be used, which is used for an O ring, for example. Among the perfluoroelastomer materials and the other materials, there are some materials that have electrostatic attraction force by themselves. By this electrostatic attraction force, the focus ring 108 the first elastic body 109a, and the second elastic body 109b can be caused to integrally function, namely, the electrostatic attraction force between the focus ring 108 and the first and second elastic materials 109a and 109b can be enhanced, and thereby stability for holding the focus ring 106 on the mounting table 20 can further be enhanced.

### [Elastic Body]

The first elastic body 109a and the second elastic body 109b are formed to have thickness that, are less than or equal to a predetermined thickness, and the first elastic body 109a and the second elastic body 109b have predetermined relative permittivity, so that the first elastic body 109a and the second elastic body 109b can cause the focus ring 108 to be electrostatically attracted to the electrostatic chuck 106, and temperature control of the focus ring 108 can be favorably performed. The first elastic body 109a and the second elastic body 109b are required to have a thickness for enhancing the sealing effect and for sufficiently supplying the heat transfer gas to the space U. Additionally, the first elastic body 109a and the second elastic body 109b are required to have predetermined relative permittivity for stably holding the focus ring 108 by the electrostatic attraction force.

Accordingly, the thickness and the relative permittivity of the first elastic body 109a and the second elastic body 109b are defined, so that a predetermined heat transfer effect and a predetermined electrostatic effect can be obtained.

As a precondition, if the width B1 of the first elastic body 109a and the width B2 of the second elastic body 109b illustrated in FIG. 2A are reduced, the space U is enlarged. However, the volumes of the first elastic body 109a and the second elastic body 109b are relatively reduced, and the electrostatic effect is reduced. As a result, it becomes difficult to stably hold the focus ring 108 by the electrostatic chuck 106. In contrast, if the width 31 of the first elastic body 109a and the width B2 of the second elastic body 109b are increased, the space U becomes smaller. The amount of the heat transfer gas that can be supplied to the space U is reduced, and the heat transfer effect is reduced. As a result, the cooling effect by the focus ring is reduced. Accordingly, it is important to determine the volume of the space U, so that a specific heat transfer effect and a specific electrostatic effect can be obtained.

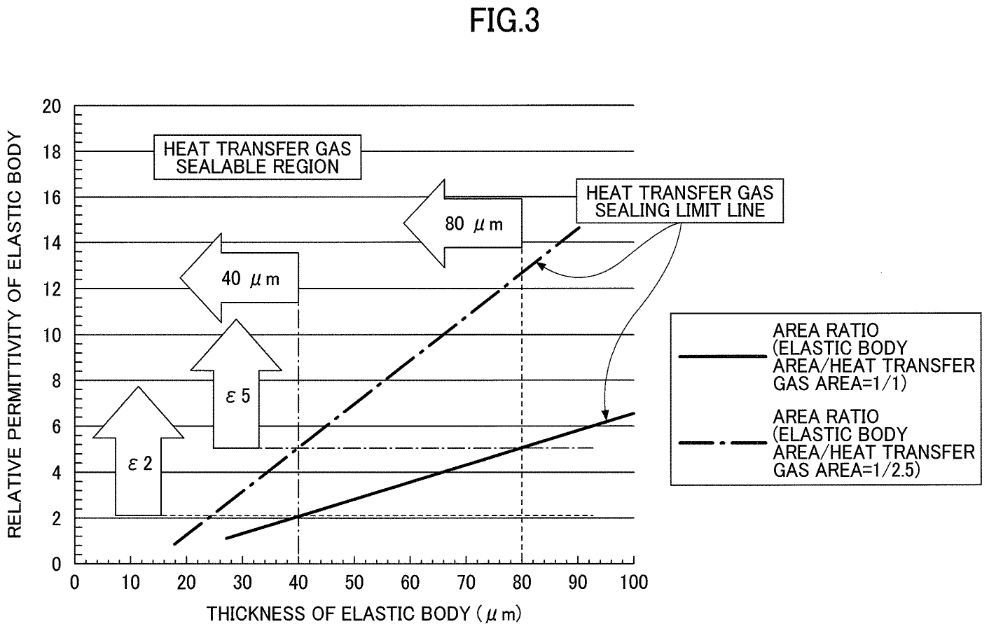

FIG. 3 illustrates an example of a relationship between the thickness of the elastic body and the relative permittivity. The horizontal axis indicates the thickness of the dielectric; and the vertical axis indicates the relative permittivity of the dielectric. Here, a total of an area Sal of the first elastic body 109a contacting the focus ring 100 and an area Sa2 of the second elastic body 109b contacting the focus ring 108, which are illustrated in FIG. 2B, is defined to be an elastic body area Sa. Furthermore, an area of the focus ring 108 between the first elastic body 109a and the second elastic body 109b is defined to be a heat transfer gas area Sg. The elastic body area Sa corresponds to a first area; and the heat transfer gas area Sg corresponds to a second area.

Between the two straight lines in FIG. 3, the solid line indicates a heat transfer gas sealing limit line for a case where an area ratio (Sa/Sg) of the elastic body area Sa with respect to the heat transfer gas area Sg is 1/1. The one-dot chain line of the two straight lines indicates the heat transfer gas sealing limit line tor a case where an area ratio (Sa/Sg) is 1/2.5. The heat transfer gas sealing limit line indicates a limit that the heat transfer gas can be sealed in the space U; and the region above the heat transfer gas sealing limit line is a heat transfer gas sealable region. Namely, in the region below the heat transfer gas sealing limit line, the focus ring 108 is peeled off from the electrostatic chuck 106 by the pressure of the heat transfer gas, so that the heat transfer gas may not be sealed (retained) inside the space U.

By comparing the heat transfer gas sealing limit line for the case where the area ratio (Sa/Sg) is 1/1, which is indicated by the solid line, and the heat transfer gas sealing limit line for the case where the area ratio (Sa/Sg) is 1/2.5, which is indicated by the one-dot chain line, it. can be seen that, as the area ratio (Sa/Sg) of the elastic body area Sa with respect to the heat transfer gas area Sg is decreased, it becomes necessary to increase the relative permittivity of the elastic body. Namely, as the area ratio (Sa/Sg) decreases, the volume of the elastic body becomes smaller, and the electrostatic attraction force is reduced, so that it is necessary to increase electrostatic attraction force by the elastic body.

From the heat transfer gas sealing limit line indicated by the solid line in FIG. 3, it. can be seen that the thickness of the first elastic body 109a and the second elastic body 109b is preferably less than or equal to 60 μm, and more preferably less than or equal to 40 μm. Namely, the relative permittivity e of the first elastic body 109a and the second elastic body 109b is preferably greater than or equal to 2; and more preferably greater than or equal to 5.

Furthermore, from the heat transfer gas sealing limit line indicated by the solid line in FIG. 3, it can be seen that the elastic body area Sa is required to be less than or equal to 1/1 times the heat transfer gas area Sg; and from the heat transfer gas sealing limit line indicated by the one-dot chain line in FIG. 3, it can be seen that the elastic body area Sa is preferably less than or equal to 1/2.5 times the heat transfer gas area Sg.

Here, the limit for sealing the heat transfer gas in the space U (the heat transfer gas sealing limit) is described.

The formula of the heat transfer gas sealing limited is defined by the following expression (1):

Fa−Fg>0 (Expression 1)

Here, Fa indicates the electrostatic attraction force (N) of the elastic body; and Fg indicates reaction force (N) by the pressure of the heat transfer gas. By the reaction force of the heat transfer gas, the focus ring 106 is pressed in a direction to peel off from the electrostatic chuck 106. The formula of the reaction force of the heat transfer gas Fg is defined by the following expression (2):

Fg=Pg×Sg (Expression 2)

Here, Pg indicates the pressure (Pa) for sealing the heat transfer gas. Furthermore, Sg indicates an area (m²) of the heat transfer gas.

The formula of the electrostatic force Fa of the elastic body is defined by the following expression (3):

Fa=(1/2)×ε₀εᵣ×SA×(V/d)² (Expression 3)

Here, Sa indicates an area (m²) of the elastic body, ε₀ indicates the dielectric constant of vacuum, εᵣ indicates the relative permittivity of the elastic body, V indicates the electrostatic attraction voltage (V), and d indicates the thickness (m) of the elastic body.

FIG. 3 indicate the heat transfer gas sealing limit line for a case where 2500 V is applied to the electrostatic chuck 106, and the pressure of the heat transfer gas is set to be 6667 Pa.

### (The Lower Limit Value of the Relative Permittivity of the Elastic Body)

From the heat transfer gas sealing limit line illustrated by the solid line in FIG. 3, it can be seen that, when the thicknesses of the first elastic body 109a and the second elastic body 109b are 80 urn, the relative permittivity ε of the first elastic body 109a and the second elastic body 109b is required to be greater than or equal to 5 so as to obtain the electrostatic effect by the first elastic body 109a and the second elastic body 109b.

Furthermore, it can be seen that, when the thicknesses of the first elastic body 109a and the second elastic body 109b are 40 μm, the relative permittivity e of the first elastic body 109a and the second elastic body 109b is required to be greater than or equal to 2 so as to obtain the electrostatic effect by the first elastic body 109a and the second elastic body 109b. Namely, the relative permittivity c of the first elastic body 109a and the second elastic body 109b is greater than or equal to 2, and preferably greater than or equal to 5.

### (The Upper Limit Value of the Relative Permittivity of the Elastic Body)

Finally, the upper limit value of the relative permittivity s of the first elastic body 109a and the second elastic body 109b is described. The upper limit value of the relative permittivity ε of the first elastic body 109a and the second elastic body 109b is preferably 500. The main reasons that the relative permittivity ε of the each of the elastic bodies is less than or equal to 500 are to facilitate production, to maintain performance of each of the elastic bodies as a perfluoroelastomer, and to meet/fulfill/satisfy a film thickness required for each of the elastic bodies.

First, the production reason is described. The relative permittivity of the first elastic body 109a and the second elastic body 109b is a value determined by a volume ratio, with respect to each of the elastic bodies, of the high relative permittivity powder added to each of the elastic bodies. For a case where the high relative permittivity powder is added to the perfluoroelastomer forming the elastic body, by considering the wetting properties of the perfluoroelastomer and the high relative permittivity powder, and condensation of the high relative permittivity powder itself, the production limit of the volume ratio, with respect to each of the elastic bodies, of the high relative permittivity powder added to each of the elastic bodies is approximately 50%.

Next, retention of the performance as the perfluoroelastomer is described. As the ratio of the added high relative permittivity powder with respect to the perfluoroelastomer forming the elastic body increases, the property of the high relative permittivity powder as the property of the the perfluoroelastomer becomes closer to the property as a dielectric, so that the property of the the perfluoroelastomer becomes closer to the property of an inorganic material. Consequently, as the elastic body, the cushion property, the gas sealing property, adhesiveness, and the strength may be reduced. Namely, from the perspective of maintaining the performance as the perfluoroelastomer, the upper limit value of the volume ratio of the added high relative permittivity powder with respect to the elastic body is also approximately 50%.

Finally, the film thickness required for the elastic body is described. The particle size of the high relative permittivity powder is generally in a range that is greater than 1 μm and less than 20 μm. Thus, when the total film thickness of the elastic body is 40 μm, if the two layers of the high relative permittivity powder with the particle size of ten and several μm are mixed, the film thickness is almost equal to the total film thickness of the elastic body. Thus, an amount of the high relative permittivity powder that can be added corresponds to the amount for a single layer. From the above description, it can be understood that the upper limit value of the volume ratio of the added high relative permittivity powder with respect to the elastic body is approximately 50%.

Based on the above-described reasons, the upper limit of the relative permittivity of the first elastic body 109a and the second elastic body 109b can be 500. Namely, the relative permittivity of the first elastic body 109a and the second elastic body 109b is a value within a range that is greater than or equal to 2 and less than or equal to 500. Furthermore, the relative permittivity of the first elastic body 109a and the second elastic body 109b is preferably greater than or equal to 5 and less than or equal to 500.

Examples of suitable high relative permittivity powders include, for example, there are titanium oxide (rutile) having relative permittivity of 114; barium titanate having relative permittivity of 2000; and lead zirconate titanate (PZT) having relative permittivity of 5000. As an example of a manufacturing method of an elastic body to which the high relative permittivity powder is added, an example can be considered in which several percent to several tens of percent of the high relative permittivity powder of any of the above-described materials is added to the elastic body, so that the relative permittivity ε of the elastic body becomes greater than or equal to 2 and less than or equal to 500, preferably greater than or equal to 5 and less than or equal to 500.

As described above, according to the structure of the mounting table 20 according to the embodiment, while the focus ring 108 is stably held by the electrostatic chuck 106 by increasing the electrostatic attraction force between the focus ring 108 and the electrostatic chuck 106, the temperature of the focus ring 108 can be favorably controlled.

The structure of the mounting table and the semiconductor processing apparatus are described above the the embodiments. However, the structure of the mounting table and the semiconductor processing apparatus according to the embodiment is not limited to the above-described embodiments, and various modifications and improvements may be made within the scope of the present invention. The subject matters described in the above-described embodiments can be combined as long as the subject matters are not incompatible.

For example, the semiconductor processing apparatus including the mounting table according to the present invention can be applied, not only to the capacitively coupled plasma (CCP: Capacitively Coupled Plasma) parallel plate semiconductor manufacturing apparatus, but also to another semiconductor manufacturing apparatus. As examples of the semiconductor manufacturing apparatus other than the capacitively coupled plasma parallel plate semiconductor manufacturing apparatus, there are an inductively coupled plasma (TCP: Inductively Coupled Plasma) apparatus; a semiconductor manufacturing apparatus using a radial line slot antenna; a helicon wave plasma (HWP: Helicon Wave Plasma) apparatus; and an electron cyclotron resonance plasma (ECR: Electron Cyclotron Resonance Plasma) apparatus.

In the present specification, the structure of the mounting table and the semiconductor processing apparatus are described by exemplifying the wafer W as the object to be processed. However, the object, to be processed is not limited to this. The object to be processed may be various types of substrates used for a liquid crystal display (LCD) or a fiat panel display (FPD); a photomask; a CD substrate; or printed circuit board, for example.

What is claimed is:

1. A mounting table comprising:
a substrate mounting area on which a substrate is placed;
a focus ring mounting area on which a focus ring is placed so that the focus ring surrounds the substrate mounting area;
an electrode that electrostatically attracts the placed focus ring;
a ring-shaped first elastic body that is placed at a first ring-shaped part of the focus ring mounting area;
a ring-shaped second elastic body that is placed at a second ring-shaped part, wherein the second ring-shaped part is placed at an inner side in a radial direction compared to the first ring-shaped part,
wherein the first elastic body and the second elastic body directly contact a back surface of the placed focus ring,
wherein the focus ring mounting area includes a recess, and the recess is provided with a supply hole that supplies a heat transfer gas to the recess,
wherein the electrode extends inward and outward in the radial direction with respect to a location of the supply hole, and
wherein the first elastic body and the second elastic body are placed in the recess of the focus ring mounting area.

2. The mounting table according to claim 1, wherein a height of the first elastic body is greater than a height of the recess, and a height of the second elastic body is greater than the height of the recess.

3. The mounting table according to claim 1, wherein the heat transfer gas supplied from the supply hole to the recess directly contacts the back surface of the placed focus ring.

4. The mounting table according to claim 1, wherein a gas flow channel is formed in which the heat transfer gas flows, so that the heat transfer gas directly contacts the back surface of the placed focus ring, and the first elastic body and the second elastic body are placed at an outer side and an inner side in a radial direction of the gas flew channel, respectively.

5. The mounting table according to claim 1, wherein the first elastic body, the second elastic body, and a bottom surface of the recess, and the back surface of the focus ring placed on the focus ring mounting area form a space.

6. The mounting table according to claim 1, wherein at least a part of a topmost surface of the placed focus ring overlaps the recess in a vertical direction.

7. The mounting table according to claim 1, wherein the mounting table electrostatically attracts the substrate placed on the substrate mounting area.

8. The mounting table according to claim 1, wherein a thickness of the first elastic body is less than or equal to 80 μm, and a thickness of the second elastic body is less than or equal to 80 μm.

9. The mounting table according to claim 1, wherein a thickness of the first elastic body is less than or equal to 40 μm, and a thickness of the second elastic body is less than or equal to 40 μm.

10. The mounting table according to claim 1, wherein a dielectric constant of the first elastic body is greater than or equal to 2 and less than or equal to 500, and a dielectric constant of the second elastic body is greater than or equal to 2 and less than or equal to 500.

11. The mounting table according to claim 1, wherein a dielectric constant of the first elastic body is greater than or equal to 5 and less than or equal to 500, and a dielectric constant of the second elastic body is greater than or equal to 5 and less than or equal to 500.

12. The mounting table according to claim 1, wherein a height of the first elastic body is greater than a height, of the recess, and a height of the second elastic body is greater than the height of the recess, and
wherein the heat transfer gas supplied from the supply hole to the recess directly contacts the back surface of the placed focus ring.

13. The mounting table according to claim 1, wherein a height of the first elastic body is greater than a height of the recess, and a height of the second elastic body is greater than the height of the recess, and
wherein a gas flow channel is formed in which the heat, transfer gas flows, so that the heat transfer gas directly contacts the back surface of the placed focus ring, and the first elastic body and the second elastic body are placed at an outer side and an inner side in a radial direction of the gas flew channel, respectively.

14. The mounting table according to claim 1, wherein the heat transfer gas supplied from the supply hole to the recess directly contacts the back surface of the placed focus ring, and
wherein a gas flow channel is formed in which the heat transfer gas flows, so that the heat transfer gas directly contacts the back surface of the placed focus ring, and the first elastic body and the second elastic body are placed at an outer side and an inner side in a radial direction of the gas flow channel, respectively.

15. A mounting table comprising:
a substrate mounting area on which a substrate is placed;
a focus ring mounting area on which a focus ring is placed, so that the focus ring surrounds the substrate mounting area;
an electrode that electrostatically attracts the placed focus ring;
a ring-shaped first elastic body that is placed at a first ring-shaped part of the focus ring mounting area;
a ring-shaped second elastic body that is placed at a second ring-shaped part, wherein the second ring-shaped part is placed at an inner side in a radial direction compared to the first ring-shaped part,
wherein the first elastic body and the second elastic body directly contact a back surface of the placed focus ring,
wherein the focus ring mounting area includes a recess, and the recess is provided with a supply hole that supplies a heat transfer gas to the recess,
wherein the electrode extends inward and outward in the radial direction with respect to a location of the supply hole,
wherein the first elastic body and the second elastic body are placed in the recess of the focus ring mounting area,
wherein a height of the first elastic body is greater than a height of the recess, and a height of the second elastic body is greater than the height of the recess,
wherein the heat transfer gas supplied from the supply hole to the recess directly contacts the back surface of the placed focus ring, and
wherein a gas flow channel is formed in which the heat transfer gas flows, so that the heat transfer gas directly contacts the back surface of the placed focus ring, and the first elastic body and the second elastic body are placed at an outer side and an inner side in a radial direction of the gas flow channel, respectively.

16. A mounting table comprising:
a substrate mounting area on which a substrate is placed;
a focus ring mounting area on which a focus ring is placed, so that the focus ring surrounds the substrate mounting area;
an electrode that electrostatically attracts the placed focus ring; and
a ring-shaped elastic body that is placed between the placed focus ring and the focus ring mounting area;
wherein the elastic body directly contacts a back surface of the placed focus ring,
wherein the focus ring mounting area includes a recess, and the recess is provided with a supply hole that supplies a heat transfer gas to the recess,
wherein the electrode extends inward and outward in a radial direction with respect to a location of the supply hole, and
wherein the elastic body defines a non-zero gap between the placed focus ring and the focus ring mounting area.

17. The mounting table according to claim 16, wherein the elastic body, the electrode, and the placed focus ring overlap in a planar view.

18. The mounting table according to claim 16, wherein at least a part of a topmost surface of the placed focus ring overlaps a recess of the focus ring mounting area in a vertical direction.

19. The mounting table according to claim 16, wherein the mounting table electrostatically attracts the substrate placed on the substrate mounting area.
